(19) United States
(12) Patent Application Publication
(10) Pub. No.: US 2025/0183046 A1
(43) Pub. Date: Jun. 5, 2025

(54) PLASMA PROCESS FOR ETCHING A MULTILAYER STACK

(71) Applicant: Tokyo Electron Limited, Tokyo (JP)

(72) Inventors: Jason Marion, Albany, NY (US); Na Li, Albany, NY (US); Yusuke Yoshida, Albany, NY (US); Yun Han, Albany, NY (US)

(21) Appl. No.: 18/529,189

(22) Filed: Dec. 5, 2023

(51) Int. Cl. H01L 21/3065; H01L 21/02; H01L 21/027; H01L 21/311

(52) U.S. Cl. CPC H01L 21/3065; H01L 21/0217; H01L 21/0274; H01L 21/31116

(57) ABSTRACT

A method for patterning includes having a substrate including a first layer, a second layer to-be-patterned disposed under the first layer, and a third layer disposed under the second layer, the first layer including a plurality of lines, each of the plurality of lines being separated by a recess, a bottom of the recess exposing a surface of the second layer; exposing the substrate to a first plasma to extend the recesses through the second layer to expose a surface of the third layer, the first plasma being generated from a first halogen based gas and a first oxidizing gas, the first halogen based gas including a carbon-containing halogen based gas; and laterally etching the recesses in the second layer using a second plasma, the second plasma being generated from a second halogen based gas and a second oxidizing gas, the second halogen based gas being a carbon-free halogen based gas.

### TECHNICAL FIELD

The present invention relates generally to methods for processing a semiconductor substrate, and, in particular embodiments, to a plasma process for etching a multilayer stack.

### BACKGROUND

Fabricating a semiconductor integrated circuit (IC) comprises integrating a network of electronic components in a monolithic structure. An array of IC units is formed on each substrate of a batch of substrates processed through a series of patterning levels. Enabled by advances in technology, a new IC node is introduced about every two years, where the component density has been doubled to reduce the unit cost of ICs and, at the same time, enhance speed and functionality. The density is doubled by shrinking feature sizes and using three dimensional (3D) transistors and memory devices. A transition from the planar field-effect transistor (FET) to 3D FETs started at the 45 nm node with FinFETs. In a FinFET, current flows in a vertical fin-shaped semiconductor channel a few nanometers thick, as if the channel of the planar FET has been rotated by 90° to protrude above the substrate. The 3D FET structures have since evolved from a FinFET to a nanosheet FET to a complementary FET (CFET). The channel of a nanosheet FET is a vertical stack of several nanosheets, a nanosheet being a few nanometers thick sheet of semiconductor. Thus, the nanosheet FET appears as if several FinFETs are laid horizontally on top of each other. Generally, the CFET is a pair of nanosheet FETs fabricated in one columnar structure. Thus, fabrication of 3D FETs, challenges plasma etch technology not only to pattern nanoscale features in complex multilayer stacks, but provide critical dimension (CD) control, at almost an atomic scale. To meet this challenge, further innovations in plasma etch methods are desired.

### SUMMARY

A method for patterning includes having a substrate including a first layer, a second layer to-be-patterned disposed under the first layer, and a third layer disposed under the second layer, the first layer including a plurality of lines, each of the plurality of lines being separated by a recess, a bottom of the recess exposing a surface of the second layer; exposing the substrate to a first plasma to extend the recesses through the second layer to expose a surface of the third layer, the first plasma being generated from a first halogen based gas and a first oxidizing gas, the first halogen based gas including a carbon-containing halogen based gas; and laterally etching the recesses in the second layer using a second plasma, the second plasma being generated from a second halogen based gas and a second oxidizing gas, the second halogen based gas being a carbon-free halogen based gas.

A method for patterning includes having a stack over a surface of a base layer of a substrate, the stack including a patterned lithography stack over a multilayer stack, the multilayer stack including a middle layer, the middle layer disposed below a top layer and above a bottom layer, the top layer being patterned to have a plurality of lines; etching through the middle layer to expose the bottom layer using a first discharge gas, the etching extending the plurality of lines from the top layer into the middle layer, where a first line of the plurality of lines has a top critical dimension (T-CD) having a first T-CD value and a bottom critical dimension (B CD) having a first B-CD value, the T CD being the width of the first line at an intersection of the top layer and the middle layer, the B CD being the width of the first line at an intersection of the middle layer and the bottom layer; and laterally etching the middle layer using a second discharge gas different from the first discharge gas, the lateral etching changing the T CD of the first line from the first T-CD value to a second T-CD value and the B CD of the first line from the first B-CD value to a second B-CD value, the difference between first T-CD value and the second T-CD value being less than the difference between first B-CD value and the second B-CD value.

A method for patterning includes having a stack over a surface of a base layer of a substrate, the stack including a patterned lithography stack over a multilayer stack, the multilayer stack including a middle layer, the middle layer disposed below a top layer and above a bottom layer, the top layer being patterned to have a plurality of lines, a first line of the plurality of lines having a width; measuring the width of the first line to have a first width; determining an etching time for laterally etching the middle layer based on the first width; etching through the middle layer to expose the bottom layer using a first discharge gas, the etching extending the plurality of lines from the top layer into the middle layer; and laterally etching, for an overetch time, the middle layer using a second discharge gas different from the first discharge gas.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a cross-sectional view of a semiconductor substrate having a multilayer stack at an intermediate stage of fabrication, where a patterned lithography stack is formed over the multilayer stack, in accordance with some embodiment;

FIG. 2 illustrates a cross-sectional view of the semiconductor substrate of FIG. 1 at a subsequent intermediate stage of fabrication, where a top layer of the multilayer stack is etched, in accordance with some embodiment;

FIG. 3 illustrates a cross-sectional view of the semiconductor substrate of FIG. 2 at a subsequent intermediate stage of fabrication, where a middle layer of the multilayer stack is exposed to a first plasma, in accordance with some embodiment;

FIG. 4A-4B illustrate cross-sectional views of the semiconductor substrate of FIG. 3 at a subsequent intermediate stage of fabrication, where a middle layer of the multilayer stack is exposed to a second plasma, FIG. 4A being at the start of the exposure and FIG. 4B being at the end of the exposure, in accordance with some embodiment;

FIG. 5 illustrates a cross-sectional view of the semiconductor substrate of FIG. 4B at a subsequent intermediate stage of fabrication, where a bottom layer of the multilayer stack is etched, in accordance with some embodiment; and

FIG. 6 illustrates a flowchart of a method for patterning a multilayer stack, in accordance with some embodiment.

### DETAILED DESCRIPTION OF ILLUSTRATIVE EMBODIMENTS

Embodiments of this invention, described in this disclosure, pertains to a plasma etch process utilized in a patterning process flow for patterning a multilayer stack formed over a layer of a substrate. The patterning results in a patterned multilayer stack having a plurality of lines used in fabricating 3D devices. Each 3D device is a combination of two distinct electronic components, where the pair of electronic components is vertically stacked in a line of a patterned multilayer stack at the same location along the line but spaced vertically by a separation layer in the multilayer stack. For example, the 3D device may be a CFET comprising, say, a p-type nanosheet FET vertically above an n-type nanosheet FET. As mentioned in the background section, the channel of a nanosheet FET is a vertical stack of several semiconductor nanosheets, referred to as channel nanosheets in this disclosure. The name “nanosheet” implies that the lateral dimensions of the channel nanosheets are large relative to its thickness. The term “nanowire” is often used if a lateral dimension is similar to the thickness. However, we have not made such a distinction in our use of the word nanosheet.

The exemplary CFET, being a pair of complementary FETs, has two nanosheet stacks, both of which are included in the multilayer stack at two different vertical positions, along with the separation layer between the two nanosheet stacks. In this disclosure, first nanosheet stack refers to the nanosheet stack above the separation layer, and second nanosheet stack refers to the nanosheet stack below the separation layer. In the exemplary patterning process flow, a single-pattern photolithography process is performed, followed by a sequence of several plasma etch steps to pattern this multilayer stack to form the plurality of lines in the patterned multilayer stack. Each of the lines is separated from adjacent lines by a recess that extends through both the nanosheet stacks (and the separation layer) and exposes a surface of a base layer of the substrate below the patterned multilayer stack. There being two nanosheet stacks in each CFET, the patterning process flow that forms the patterned multilayer stack has to meet specifications for two critical dimensions (CDs), viz., a width of the first nanosheet stack and a width of the second nanosheet stack. Embodiments of the plasma etch process, described in this disclosure, provide the means to achieve a desired difference between the two CDs. Using the described embodiments of the invented plasma etch process provides an advantage of etching through the separation layer to form a patterned separation layer comprising a plurality of lines, where a difference between a width of each line along a top surface of the separation layer and a width of the same line along a bottom surface of the separation layer is precisely controlled, as described in detail further below. The specified width of the first nanosheet stack may be achieved by controlling the single-pattern photolithography process, and the specified width of the second nanosheet stack may be achieved by controlling the etching through the separation layer, as will be apparent from a description of a process flow using the invented plasma etch process described further below in this disclosure.

It is clarified herein that a “line” in the patterned multilayer stack may be a line segment, i.e., each line may have two lateral dimensions in two orthogonal directions of a horizontal plane, the horizontal plane being at some vertical position in the multilayer stack line segment. However, because lateral dimensions have been scaled aggressively, in the more advanced technology nodes, lines segments are often patterned using two patterning processes: one patterning process forming parallel lines in one direction, and a subsequent patterning process cutting these lines in the orthogonal direction forming line segments. It is understood that the innovative aspects of the invented plasma etch process may be applied to any patterning process for patterning lines, where each of the patterned lines has two critical dimensions that are parallel to each other but defined at two different vertical positions in the layer being patterned.

It is desired that the patterning process flow (which forms the patterned multilayer stack) use a process control method that controls both the width of the first nanosheet stack and the width of the second nanosheet stack. Typically, inline CD control controls a linewidth of a line of a patterned layer as observed in a top-view image of a pattern of lines. A method for inline CD control of the patterned multilayer stack to control two linewidths at two different vertical locations inside the same line is described in detail further below.

As known to persons skilled in the art and explained herein, the lateral dimensions of each nanosheet stack affect the electrical characteristics of the respective nanosheet FET, hence the widths of the two nanosheet stacks of the CFET are desirably included in a set of CDs for inline process control of an IC manufacturing process flow that includes fabricating CFETs.

In general, the FET is an active electronic component having a channel region in physical contact with a source region and a drain region at two opposite ends of the channel region. The source, drain, and channel regions comprise appropriately doped semiconductor materials and are so named because electric charge may flow from the source to the drain through the channel. In an n-type FET, the channel charge is of negative polarity, and in a p-type FET, the channel charge is of positive polarity. For the nanosheet FET, the channel comprises a set of “channel nanosheets” of the nanosheet stack, where each channel nanosheet is sandwiched between two sacrificial nanosheets. At an intermediate stage of the fabrication flow, the sacrificial nanosheets are replaced by a gate electrode and a very thin gate insulator layer, collectively referred to as a gate stack, where the gate electrode is spaced from the channel by the gate insulator. Typically, the gate stack comprises a high-k dielectric and a metal gate (HKMG), and the integration flow of the gate stack is referred to as a replacement metal gate (RMG) flow. Since the gate stack replaces the sacrificial nanosheets, the gate stack wraps around a surface of the channel region, thus giving the device a gate-all-around FET (or GAAFET) architecture.

In each of the channel nanosheets, the charge flow is in a lateral direction (normal to the thickness direction of the nanosheet). The channel charge may be controlled over a range of about three to ten orders of magnitude by varying an electric field normal to the flow (the so-called field effect of the FET), which may be adjusted by varying a respective bias voltage applied to the gate electrode. Two edge regions at two opposite edges of each channel nanosheet along a lateral direction perpendicular to the direction of the charge flow are portions of the source and drain, referred to as the source-drain (S/D) extension regions. Generally, the S/D extension regions are formed self-aligned to the gate electrode. All the S/D extension regions on one side of the channel nanosheet are connected physically to a main S/D region formed along that side in the space between adjacent nanosheet transistors. The main S/D region is typically formed by epitaxial growth from the channel nanosheets merging in the recessed space adjacent to the nanosheet stack. All the S/D extension regions on the opposite side are, likewise, connected physically to a respective main vertical S/D region along the opposite side.

During circuit operation, the channel current flows in the source-to-drain direction (or drain-to-source direction, depending on the polarity of the channel charge). Accordingly, the channel current flowing through each nanosheet transistor is roughly directly proportional to a lateral dimension (or, a width) of its nanosheet stack in the direction perpendicular to the source-to-drain direction. Each of the nanosheet stacks have another lateral dimension (or, another width) in a direction parallel to the direction of the channel current (i.e., parallel to the source-to-drain direction). The width in this direction affects the channel current of the respective nanosheet transistor in a different way. The width of the nanosheet stack in the direction parallel to the current flow is a sum of a combined length of the two S/D extension regions and a length of the channel region (between the two S/D extension regions). Of these, generally, variations in the length of the channel region in the direction parallel to the current flow reflect variations in the length of the gate electrode instead of variations in the width of the nanosheet stack. Recall that the S/D extension regions are formed self-aligned to the gate electrode (or the sacrificial structure replaced by the metal gate electrode in an RMG flow). Thus, to first order, the length of the channel region is fixed by the length of the gate electrode. On the other hand, any change in the width nanosheet stack in the direction parallel to the current flow is reflected directly in a change in the combined lengths of the S/D extension regions. A change in the length of the S/D extension regions changes the parasitic resistance of the S/D region, thereby altering the channel current.

Since the lateral dimension of the nanosheet stack in either of the two directions (the direction parallel to the current and the direction perpendicular to the current) affect the channel current, the patterning process flow for forming multilayer stack lines needs to meet specifications for the width of the first nanosheet stack and the width of the second nanosheet stack, irrespective of the direction in which the lines are being patterned.

As mentioned above, the multilayer stack in this disclosure is for fabricating a 3D device, having two stacked electronic components in the multilayer stack. In general, the components can be of various types. A first component is to be formed in a top layer, and a second component is to be formed in a bottom layer. A middle layer is a separation layer between the top layer and the bottom layer. Suitable compositions of the top layer, the bottom layer, and the middle layer may be selected depending on the types of the components to be fabricated. However, independent of the type of component, at the end of the patterning process, specifications for a width of a line of the top layer and specifications for a width of a line of the bottom layer have to be met. An inventive aspect of a method for patterning multilayer stacks with such a constraint is etching recesses through the middle layer with a plasma etch process having process parameters to control a sidewall profile. The process parameters are adjusted such that the controlled sidewall profile provides, for each line formed between adjacent recesses in the middle layer, a desired difference between two widths of the same line, viz., a width of the line at the top of the middle layer and a width of the line at the bottom of the middle layer.

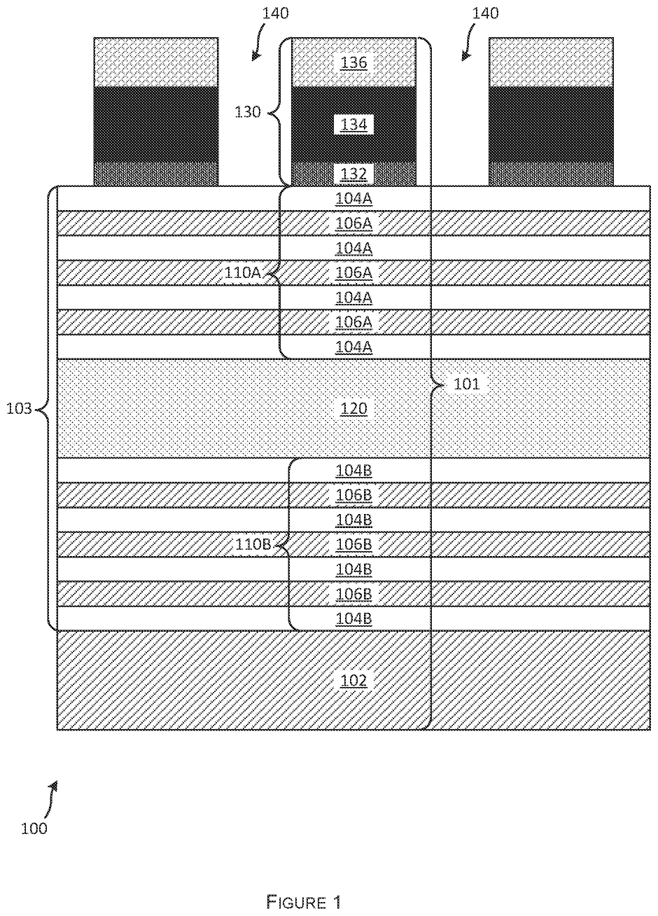

An example process flow for patterning a substrate having a multilayer stack for fabricating a 3D device is described with reference to FIGS. 1-5. In this illustrative example, for specificity, the 3D device is a CFET 100 with two vertically stacked nanosheet FETs as its constituent electronic components.

FIG. 1 illustrates a cross-sectional view of a stack 101 over a surface of a base layer 102 of a substrate. The stack 101 comprises a multilayer stack 103, shown disposed over the base layer 102 of the substrate and a lithography stack 130 having a plurality of lines, shown disposed over the multilayer stack 103. The 3D device, being a CFET with two vertically stacked nanosheet FETs, the multilayer stack 103 has a first nanosheet stack as its top layer 110A and a second nanosheet stack as its bottom layer 110B. Between the top layer 110A and the bottom layer 110B, is a middle layer 120 for electrical isolation between the top layer 110A and the bottom layer 110B. Each nanosheet stack in FIG. 1 comprises alternating sacrificial nanosheets (104A in top layer 110A or 104B in the bottom layer 110B) and channel nanosheets (106A in top layer 110A or 106B in the bottom layer 110B). The composition of the sacrificial nanosheets 104A/104B are selected such that there is an etch chemistry available to remove the sacrificial nanosheets 104A/104B selectively. In the example illustrated in FIG. 1, each nanosheet stack has three channel nanosheets 106A/106B comprising, for example, silicon (Si) and four sacrificial nanosheets 104A/104B comprising, for example, silicon germanium (Si₁₋ₓGeₓ). Depending on the number of channel nanosheets, each of the nanosheet stacks (i.e., the top layer 110A and the bottom layer 110B) may have a thickness of about 20 nm to about 120 nm, e.g., 50 nm. In this example, the base layer 102 of the substrate may be, for example, part of a bulk semiconductor wafer, also comprising silicon. It is understood that, in other embodiments, other semiconductors (e.g., GaAs) may be used.

At the intermediate stage of fabrication of the CFET 100, illustrated in the cross-sectional view in FIG. 1, the middle layer 120, separating the top layer 110A and the bottom layer 110B, comprises a dielectric (e.g., silicon oxide, silicon nitride, silicon oxynitride, germanium oxide, silicon carbonitride, and the like) to provide electrical isolation between the FET in the top layer and that in the bottom layer. In the example, illustrated in FIG. 1 the middle layer 120 comprises silicon carbonitride. In various embodiments, a thickness of the middle layer 120 may be about 20 nm to about 150 nm, e.g., 50 nm.

The example patterned lithography stack 130, illustrated in the cross-sectional view of the substrate in FIG. 1, includes a patterned hardmask formed over the top layer 110A, the patterned hardmask comprising a patterned first hardmask layer 134 over a patterned second hardmask layer 132, and a patterned resist mask 136 over the first patterned hardmask layer 134. The patterned resist mask 136 may be formed using a suitable photolithography technique, for example, 13 nm extreme ultraviolet (EUV) lithography. In addition, there may be an optional coating (not shown) below the resist mask 136, such as an EUV underlayer, often used to enhance adhesion, enhance resist sensitivity, reduce line width roughness (LWR), and reduce stochastic defects, hence improve the pattern quality.

The patterned resist mask 136 may be used as an etch mask in a pattern transfer etch process using, e.g., an anisotropic reactive ion etching (RIE) technique to form the patterned first hardmask layer 134 and the patterned second hardmask layer 132 and expose a surface of the top layer 110A of the multilayer stack 103, as illustrated in FIG. 1.

In various embodiments, the patterned first hardmask layer 134 may be comprising, e.g., a silicon oxide layer having a thickness of about 50 nm to about 100 nm, e.g., 70 nm, and the patterned second hardmask layer 132 may be comprising, e.g., a titanium nitride layer having a thickness of about 15 nm to about 30 nm, e.g., 20 nm. Other hardmask materials, including silicon carbide, silicon oxynitride and silicon carbonitride may also be used, but the hardmask materials have to be selected such that the patterned hardmask provides sufficient etch selectivity to be used as etch masks during etching the various layers of the multilayer stack 103.

Completing the etching steps that expose the top layer 110A at the bottom of a recess pattern 140 completes forming the lithography stack 130. A thickness of the resist remaining in a patterned resist mask 136, after the patterned lithography stack 130 has been formed, may be from 10 nm to about 30 nm, e.g., 20 nm. The lithography stack 130, illustrated in FIG. 1, is used as an etch mask to etch the top layer 110A by etching the top layer 110A using an anisotropic plasma etch process with, for example, bromine, chlorine, or fluorine etch chemistry. Accordingly, a process gas used for the plasma may include HBr, Cl₂, or a fluorine containing gas such as NF₃, SF₆, CF₄, and CₓH_{y}F_{1-x-y}.

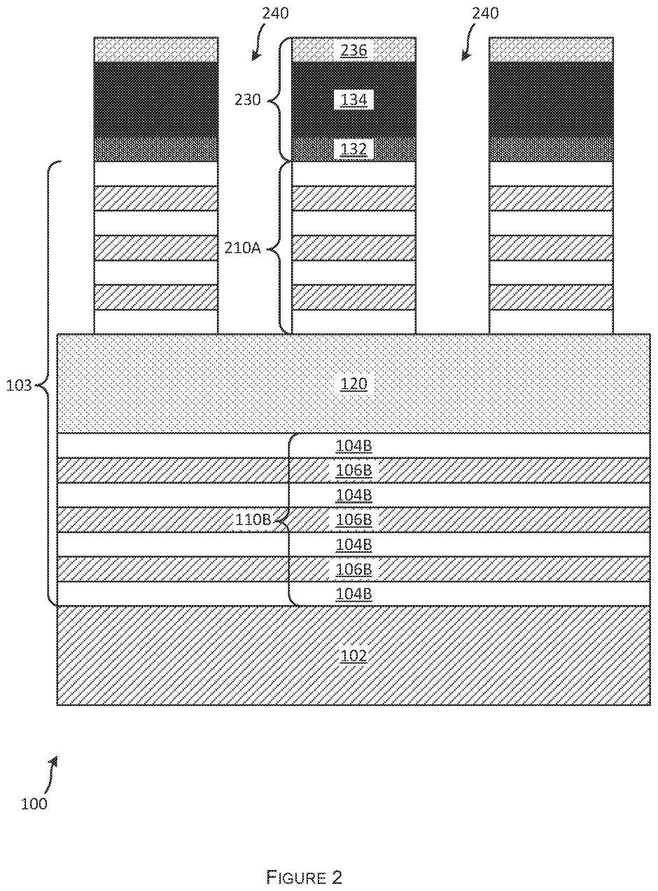

FIG. 2 illustrates a cross-sectional view of the CFET 100 after forming a patterned top layer 210A. As illustrated in FIG. 2, the etch process used to form the patterned top layer 210A has extended the recess 140 through the top layer 110A to form recess 240 that exposes a surface of the middle layer 120, thus forming a plurality of lines in the patterned top layer 210A, covered by a lithography stack 230 remaining after forming the recess 240 is completed. In the example lithography stack 230, illustrated in FIG. 2, there is a thinner resist mask 236 remaining over the first hardmask layer 134. In some other embodiment, the resist loss during etching may be more severe and completely remove the resist mask 136 before the recess 240 is completely formed. The patterned hardmask, i.e., the combined patterned first hardmask layer 134 and patterned second hardmask layer 132, would then be an etch mask for the remaining portion of the patterning process flow for patterning the multilayer stack 103.

It is noted that, in the exemplary patterning process flow, the patterned top layer 210 is formed using a simple single-patterning technique. This description of patterning the top layer 110A is not intended to be construed in a limiting sense. In some other embodiment, a different lithography technique may be used to form the patterned top layer 210. For example, if the pattern has a linewidth beyond the resolution limit of the optical system then a multiple patterning method, such as self-aligned double patterning (SADP) using a sidewall image transfer (SIT) technique may be used to etch the pattern of lines in the patterned top layer 210A. The use of the simpler single-patterning method may be enabled by the higher resolution of EUV lithography. In this patterning process flow, inline CD control of the top layer 210A may be achieved by controlling a width of the lithography stack 130 when it is patterned using, for example, EUV lithography.

After exposing the surface of the middle layer 120, an invented plasma etch process that is suitable for etching the example middle layer 120 in the multilayer stack 103 is performed. By etching through the middle layer 120 using the patterned top layer 210A and the lithography stack 230 as an etch mask, the recess 240 may be extended deeper to expose a surface of the bottom layer 110B. In order to achieve that, the etch chemistry has to have a high selectivity to the material adjacent below the middle layer 120 and the materials exposed along sidewalls of the recess 240 (except the small amount of remaining resist). This includes the hardmask materials, all the materials in the patterned top layer 210A, and the material of the uppermost layer in the bottom layer 110B (which is the material of the sacrificial nanosheet 104B in FIG. 2). In addition, by properly setting adjustable process parameters that control the sidewall profile, the etch process has to provide, for each line, a desired difference between two widths of the same line, viz., a width of the line at the top of the middle layer 120 and a width of the line at the bottom of the middle layer 120.

As mentioned above, the multilayer stack 103 is for forming the CFET 100. Accordingly, both the top layer 110A and the bottom layer 110B comprise a stack of alternating semiconductor nanosheets, alternating between a sacrificial nanosheet comprising a first semiconductor and a channel nanosheet comprising a second semiconductor. Furthermore, the middle layer 120 comprises a dielectric. In the example patterning process described with reference to FIGS. 1-5, the sacrificial nanosheets 104A/104B comprise crystalline silicon-germanium alloy (Si₁₋ₓGeₓ) and the channel nanosheets 106A/106B comprise crystalline silicon (Si), and the middle layer 120 comprises silicon carbonitride (SiCN).

The invented etch process (for etching the middle layer 120 in FIG. 2) is performed in two steps. First, a main etch process is performed on the substrate after the plurality of lines has been formed in the patterned top layer 210A, such as the CFET 100, illustrated in FIG. 2. In some embodiments, the main etch process is performed in situ after the patterned top layer 210A has been formed. In the main etch process, the substrate is exposed to a first plasma generated by ionizing a first discharge gas to etch through the middle layer 120 and exposing a surface of the bottom layer 110B adjacent below the middle layer 120. The plasma etch technique used for the main etch may be an anisotropic RIE technique. The first discharge gas may be a gaseous mixture of a first halogen based gas and a first oxidizing gas. In some embodiments, the first halogen based gas comprises gases of the form CₓH_{y}F_{1-x-y}, such as CH₃F, CHF₃, and CH₂F₂ and the first oxidizing gas comprises, for example, oxygen such as O₂, O₃, CO, and CO₂. In some embodiments, the CₓH_{y}F_{1-x-y} gas may be replaced by NF₃, SF₆ or any fluorine containing gas. In some other embodiment, the oxidizing atoms may comprise nitrogen.

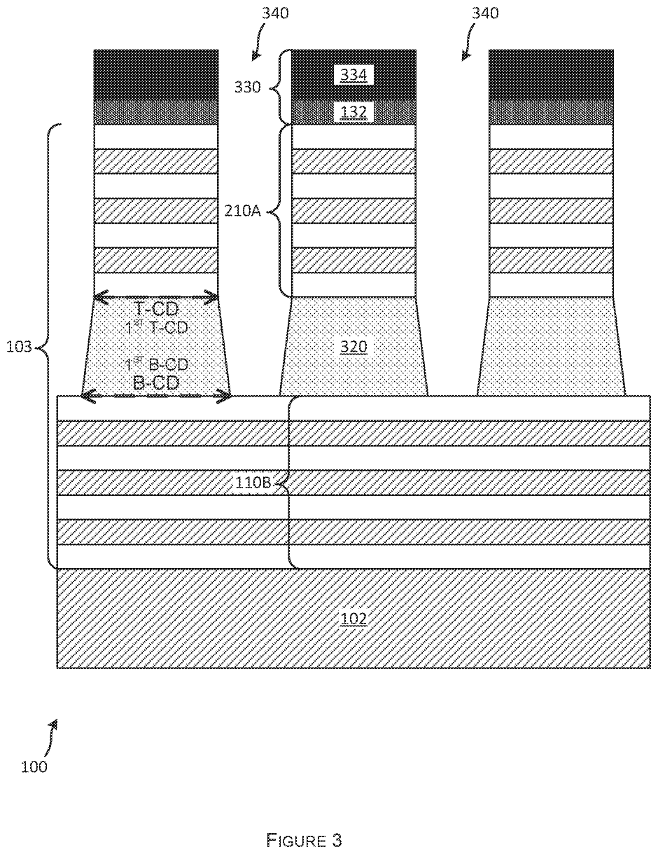

In the example embodiment of the main etch illustrated in FIG. 3, the first halogen based gas is methyl fluoride (CH₃F) and the first oxidizing gas is molecular oxygen (O₂). Other relevant process parameters used for the main etch process include a chamber pressure of about 5 mTorr to about 100 mTorr, a flow rate of CH₃F from about 2 sccm to about 500 sccm, and a flow rate of O₂ from about 2 sccm to about 100 sccm. In addition, there may be an inert carrier gas comprising, for example, argon flowing through the chamber at a flow rate of about 50 sccm to about 1500 sccm. Radio frequency (RF) power sources of about 25 W to about 1500 W at frequencies of 400 kHz to about 40 MHz, for example, 13.56 MHz may be used to sustain the first plasma.

A cross-sectional view of the CFET 100 after the main etch process is complete is illustrated in FIG. 3. During the etching, there may be some loss of hardmask material, hence there is a thinner first hardmask layer 334 and a thinner lithography stack 330 in the cross-sectional view in FIG. 3. The main etch process etches the middle layer 120 and “soft-lands” on the top of the bottom layer 110B, exposing its top surface with little or no recess. As seen in the cross-sectional view of CFET 100 in FIG. 3, the main etch process has extended the recess 240, thereby forming a deeper recess 340. By forming the deeper recess 340, the main etch has formed a plurality of lines in an intermediate patterned middle layer 320.

In lines formed by anisotropic RIE, the sidewall surfaces may be sloped because passivation and etching may occur simultaneously at the exposed surfaces of the layer being etched. In the example embodiment in FIG. 3, surface passivation may occur because of carbon in the first plasma contributing to polymer byproducts and oxygen in the first plasma reacting with silicon in the silicon carbonitride to form silicon oxide. The reaction with fluorine in the first plasma may produce volatile byproducts that are removed with the gas flow through the chamber. As expected, the lines illustrated in FIG. 3 have sloped sidewall surfaces. The slope depends on relative rates of passivation and etching of the sidewall surfaces. In some embodiments, the main etch is such that etching through the intermediate patterned middle layer 320 etches the sidewall surfaces to be sloped in a direction such that a horizontal spacing between adjacent sidewall surfaces is reducing with increasing vertical distance from an intersection of the intermediate patterned middle layer 320 and the patterned top layer 210A. Accordingly, in these embodiments, each of the plurality of lines is wider at the bottom of the intermediate patterned middle layer 320 relative to its width at the top of the intermediate patterned middle layer 320.

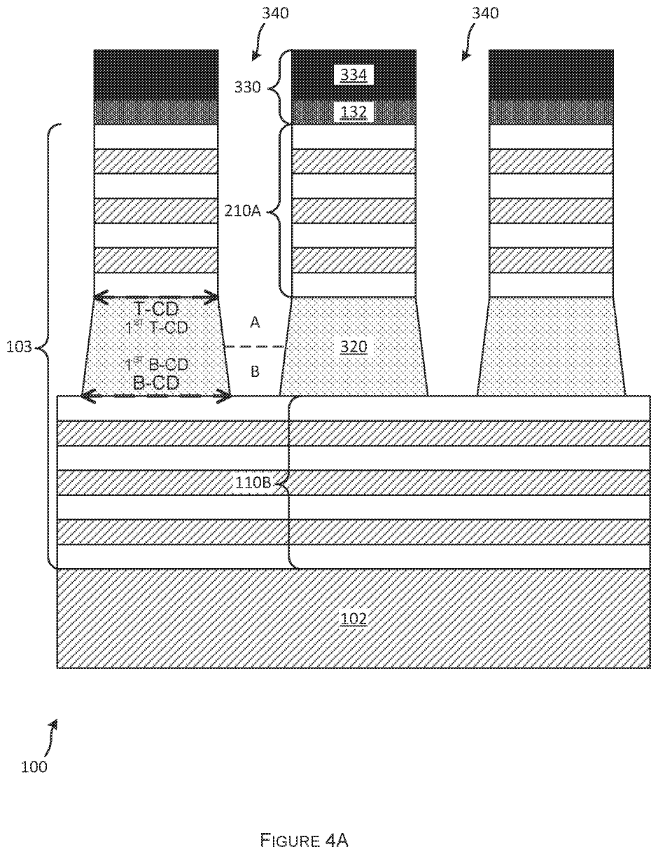

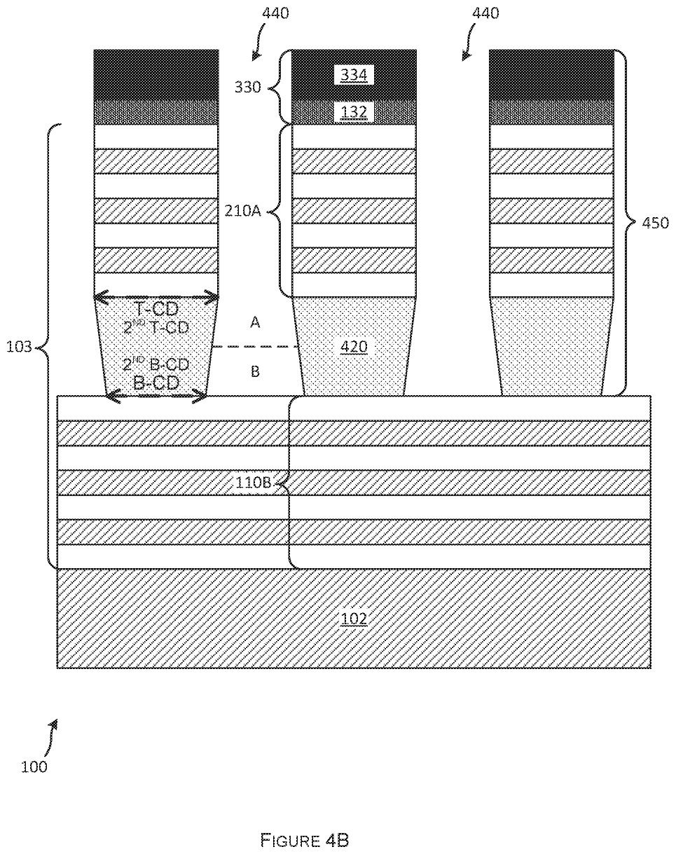

At the end of the main etch process, an overetch process is performed. In some embodiments, the overetch process is performed in situ by exposing the substrate to a second plasma after the main etch process is completed. The structure of the CFET 100 in FIG. 3 is repeated in FIG. 4A to describe the conditions at the beginning of the overetch process. The structure of the CFET 100 at the end of the overetch process is illustrated in the cross-sectional view in FIG. 4B.

As illustrated in FIG. 3 and in FIG. 4A, each line has a top critical dimension (T-CD) and a bottom critical dimension (B-CD), where T-CD is the width of the line at an intersection of the top layer and the middle layer (e.g., the patterned top layer 210A and the intermediate patterned middle layer 320), and B-CD is the width of the same line at an intersection of the middle layer and the bottom layer (e.g., the intermediate patterned middle layer 320 and the bottom layer 110B). Each line having sloped sidewalls implies that its width, at any horizontal plane in the intermediate patterned middle layer 320, depends on a vertical distance of the plane from an intersection of the intermediate patterned middle layer 320 and the patterned top layer 210A. Consider a first line of the plurality of lines in the intermediate patterned middle layer 320 in the example embodiment illustrated in FIG. 4A. At the start of the overetch process, the first line has a first B-CD and a first T-CD, and the sidewall profile is such that the first B-CD is greater than the first T-CD. At the end of the overetch process, the sidewall profile is altered, as illustrated in FIG. 4B. The overetch process adjusts the B-CD by adjusting the sidewall profile. As explained further below, a desired sidewall profile is achieved by adjusting vertical gradients in concentrations of process gases in the recess 340. The vertical diffusion rates of various gaseous species being different causes an upper portion of the recess 340 (indicated as region-A in FIGS. 4A-4B) to be rich in a slowly-diffusing species, while a lower portion of the recess 340 (indicated as region-B in FIGS. 4A-4B) is rich in a fast-diffusing species. In the embodiments of the methods for patterning, described in this disclosure, adjusting the process parameters of the overetch process to adjust the vertical gradients in concentrations of process gases inside the recess 340 provides the advantage of controlling the T-CD and B-CD independently.

It is noted that, since the first B-CD is greater than the first T-CD, standard inline instruments for linewidth measurement may be used to measure the first B-CD of the first line. As described in detail further below, this measurement, along with a similar measurement for the first T-CD may be used during process development to develop a model to be used for an inline process control method for CD control of a width of the patterned top layer 210A and a patterned bottom layer to be formed subsequently. The measurement of the first T-CD may be taken earlier, after the patterned top layer 210A has been formed and before the main etch for etching the middle layer 120 has started (see FIG. 2).

As illustrated in FIG. 4B, the overetch process alters the sidewall profile to change the first T-CD to a second T-CD and the first B-CD to a second B-CD. It is noted that a change in the T-CD of the first line is close to zero. This feature of the overetch process is obtained by design during process development. The process parameters of the overetch process may be adjusted by process design to enable the overetch process to etch laterally. Laterally etching the intermediate patterned middle layer 320 etches the sidewall surfaces to enlarge the recess 340 and shrink the lines in the intermediate patterned middle layer 320, as seen by comparing the example pattern of lines and the recess 340 (illustrated in FIG. 4A) with the recess 440 and the lines in the final patterned middle layer 420 (illustrated in FIG. 4B). Moreover, the lateral etch rate at the sidewall surfaces depends on the vertical position inside the recess 340. The overetch process in the invented plasma etch process is designed to achieve a lateral etch rate that reduces with increasing vertical distance from an intersection of the intermediate patterned middle layer 320 and the bottom layer 110B. In other words, the etch rate is highest at the intersection between middle layer and the bottom layer (e.g., the final middle layer 420 and the bottom layer 110B) and least at intersection between the middle layer and the top layer (e.g., the final middle layer 420 and the top layer 110A).

As mentioned above, the invented plasma etch process is used to achieve a desired difference between two CDs, viz., a CD of the top layer (e.g., the patterned top layer 210A) and a CD of the bottom layer (e.g., the bottom layer 110B when it is patterned at a subsequent etch process step). As explained above, the CD of the top layer is set by the width of the lithography stack 130, which was used as the etch mask to etch the top layer 110A to form the patterned top layer 210A (see FIGS. 1-2). For the first line of the multilayer stack 103 in FIG. 4B, the CD of the patterned top layer 210A has already been set. In the example patterning process flow for patterning the multilayer stack 103, the stack 450 above the bottom layer 110B (as indicated in FIG. 4B) may be used as the etch mask for patterning the bottom layer 110B. Thus, the second B-CD of the first line determines the CD of the bottom layer (when the bottom layer 110B is patterned at a subsequent etch process step). In order to have the second B-CD match the desired value, the overetch process needs to control a reduction in B-CD from its first B-CD to the desired CD of the bottom layer. An example overetch process is described next.

As mentioned above, the overetch process of the invented plasma etch is performed by exposing the substrate to a second plasma. The second plasma is generated by ionizing a second discharge gas different from the first discharge gas. The second discharge gas may be a gaseous mixture of a second halogen based gas and a second oxidizing gas. The second halogen based gas comprises, for example, nitrogen trifluoride (NF₃) and the second oxidizing gas comprises, for example, oxygen. In these examples of the second halogen based gas the halogen atoms are the fluorine atoms and the oxidizing property is from the oxygen atoms.

As explained above, it is the vertical gradient of the lateral etch rate that controls the second B-CD, which is, in essence, the CD for the bottom layer, after the bottom layer 110B is patterned. The vertical gradient of the lateral etch rate is determined by the relative concentrations of the second halogen based gas and a second oxidizing gas of the overetch process. In the upper portion of the recess 340 (i.e. in region-A), the gaseous mixture has a higher percentage of the oxidizing gas such that the lateral etching of the patterned middle layer 320 is retarded. In contrast, in the lower portion of the recess 340 (i.e. in region-B), the gaseous mixture has a higher percentage of the halogen gas, hence the lateral etching of the patterned middle layer 320 is enhanced. The ability to control the vertical profile of the relative concentrations by controlling the process parameters of the overetch process, for example, the relative flow rates of the halogen gas and the oxidizing gas provides the invented methods the ability to control two CDs independently at the same x-y location of the multilayer stack 103.

In the example embodiment of the overetch process illustrated in FIG. 4B, the second halogen based gas is nitrogen trifluoride (NF₃) and the second oxidizing gas is molecular oxygen (O₂). In addition, there may be an inert carrier gas comprising, for example, argon in the gaseous mixture flowing through the chamber at a flow rate of about 50 sccm to about 1500 sccm. The chamber pressure may be about 5 mTorr to about 100 mTorr. Radio frequency (RF) power sources of about 25 W to about 1500 W at a frequencies of 400 kHz to about 40 MHz, for example, 13.56 MHz may be used to sustain the second plasma.

As mentioned above, at the completion of the main etch process (i.e., at the beginning of the overetch process) of the example embodiment, each line of the plurality of lines in the intermediate patterned middle layer 320 is narrower at the top of the intermediate patterned middle layer 320 than at the bottom, as illustrated in FIG. 4A). The main etch process is designed to have enough oxygen in the first plasma so the sidewall profile may be sufficiently sloped to ensure that the first B-CD of the first line is larger than the desired CD of the bottom layer 110B. The overetch process, performed after the main etch, would then reduce the B-CD to a second B-CD, which meets a specification for the desired value of the CD for the bottom layer.

It is not desirable to reduce the first T-CD because that would produce an undesirable undercut. An undercut should be avoided to ensure the sidewall profile remains smooth for downstream sidewall, etch, material replacement and ultimately for proper charge control for final device functionality. Hence the overetch process is designed to achieve a high lateral etch rate at the bottom of the recess 340 that reduces with increasing height above the top surface of the bottom layer 110B, attaining, ideally, a lateral etch rate equal to zero at a horizontal plane going through the intersection of the patterned top layer 210A and the intermediate patterned middle layer 320. Generally, it is not desirable for the sidewall profile of the patterned lines of the final patterned middle layer 420 to be such that the lines have either an undercut, bulge, or notch. Thus, optimal process parameters of the invented etch process for etching the middle layer 120 in FIG. 2 may be selected such that the width of the first line changes gradually and monotonically from the second T-CD value to the second B-CD value in the middle layer.

A ratio of the lateral etch rate at the plane of the top surface of the bottom layer 110B to that at the plane going through the intersection of the patterned top layer 210A and the intermediate patterned middle layer 320 is, on the average, equal to a ratio of the reduction in B-CD to the reduction in T-CD. The reduction in B-CD is the difference between the first B-CD and the second B-CD, and the reduction in T-CD is the difference between the first T-CD and the second T-CD. This ratio is referred to as “lateral etch ratio” in this disclosure. A lateral etch ratio of one equates to the difference between first B-CD and the second B-CD being equal to the difference between first T-CD and the second T-CD. In the embodiments of the invention described in this disclosure, the lateral etch ratio is less than one. Indeed, as mentioned above, it is undesirable to change T-CD at all, hence a very low lateral etch rate is desired near the top surface of the intermediate patterned middle layer 320. This may be achieved if the rate of passivation is kept high near the top surface of the intermediate patterned middle layer 320 by, for example, having a relatively high ratio of oxygen (oxidizing agent passivating the sidewall) to fluorine (etchant) compared to the ratio near the bottom surface of intermediate patterned middle layer 320. In the embodiments described in this disclosure, the aspect ratio of the recess 340 is generally high, for example, between about 10 to about 100. A diffusion rate of fluorine in high aspect ratio recesses being higher than a diffusion rate of oxygen, the upper portion of the recess 340 (indicated as a region-A in FIGS. 4A-4B) may be more rich in oxygen, while the lower portion of the recess 340 (indicated as a region-B in FIGS. 4A-4B) may be more rich in fluorine. In general, a vertical profile of a ratio of the passivation rate and the removal rate of the sidewall may be adjusted by adjusting vertical concentration profiles of an oxidizing species (e.g., oxygen radicals) and an etchant species (e.g., fluorine radicals) in the recess 340.

In the example embodiment, the lateral etch ratio may be controlled by controlling a flow of the second halogen based gas (NF₃ in the example in FIGS. 4A-4B) and a flow of the second oxidizing gas (O₂ in the example in FIGS. 4A-4B) at a “flow rate ratio,” where the flow rate ratio is defined to be a ratio of a flow rate of the halogen gas (NF₃) to a flow rate of the oxidizing gas (O₂), in this disclosure.

In an embodiment, the difference between first T-CD value and the second T-CD value is less than 0.01 times the difference between first B-CD value and the second B-CD value, i.e., the lateral etch ratio being less than 0.01. Ideally, a lateral etch ratio equal to zero is desired because there would be no undercut (reduction in T-CD would be zero), while any desired reduction in B-CD may be achieved by adjusting an overetch duration time.

During process development, experiments may be performed, where, for example, multiple test substrates are prepared, with each test substrate being processed with a respective overetch process having a respective flow rate ratio. The etch ratio for each test substrate may be measured using, for example, transmission electron microscopy (TEM) to select an overetch process, where any substrate processed using this overetch process would have its etch ratio less than a first etch ratio, for example, less than 0.01

Once such an overetch process has been selected, another experiment may be performed, where, for example, multiple test substrates are prepared, with each test substrate being processed with the selected overetch process but a respective overetch duration time. During the experiment, after the main etch process is completed, an inline CD measurement may be performed on each wafer to measure a respective first B-CD, and at the end of the overetch process, the second B-CD of each substrate may be measured using, for example, transmission electron microscopy (TEM).

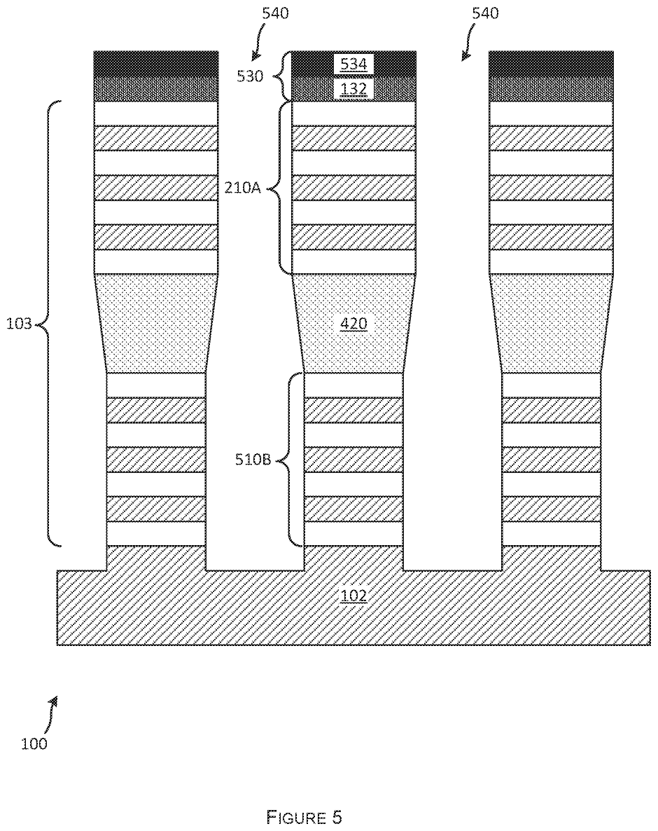

The above may be repeated with multiple sets of test wafers, where each set has a different width of the top layer (e.g., width of the patterned top layer 210A, as shown in FIG. 2). Alternatively, the width of the top layer may be varied by preparing the test substrates using, for example, an IC design that includes a set of test 3D devices. As mentioned above, each 3D device comprises a first component to be formed in a top layer (e.g., the patterned top layer 210A in FIG. 2), and a second component is to be formed in a bottom layer (e.g., the patterned bottom layer 510B in FIG. 5). Each test 3D device of the set of devices would be designed for a fixed width of the second component but a different width for the first component. During fabrication, each different designed width results in a respective different width of the top layer of the multilayer stack (e.g., the patterned top layer 210A in FIG. 2).

The results may be used to obtain a computational model, e.g., a mathematical, AI-based, heuristic, etc., that relates overetch duration time, which is the time for lateral etching, and respective reduction in B-CD.

The computational model may be used to compute an overetch duration time for a desired reduction in B-CD and applied to control the CD of the top layer and the CD of the bottom layer during manufacturing.

First, an inline CD control method may be implemented where the CD of the top layer is controlled by controlling the lithography process used to pattern the top layer. As known to a person skilled in the art, a standard method of controlling CD in lithography may be used. For example, a test substrate selected from a batch of substrates may be processed with an exposure dose and focus matrix and the respective CDs of patterned resist lines may be measured to select an appropriate exposure and focus for processing all the substrates of the batch.

Subsequently, after the main etch for patterning the middle layer is completed, a test wafer may be selected from the batch of substrates and a measurement made to determine its first B-CD. Then a desired reduction in B-CD may be calculated as the difference between the measured first B-CD and a desired second B-CD for the patterning process. After calculating the desired reduction in B-CD, the mathematical model may be used to compute a respective overetch duration time for processing all the substrates of the batch.

In some embodiments, the second B-CD value may be greater than or equal to the first T-CD value. In some other embodiments, the second B-CD value may be less than the first T-CD value.

As illustrated in FIG. 5, after completing the overetch process, the final patterned middle layer 420 may be used as an etch mask to anisotropically etch the bottom layer 110B to expose a surface of the base layer 102 of the substrate, thus extending the recess 440 to form the recess 540 and the plurality of lines in a patterned bottom layer 510B. In some embodiments, such as the example illustrated in FIG. 5, the etching is used to extend the recess 440 further, such that the recess 540 form recesses in the first layer 102 of the substrate.

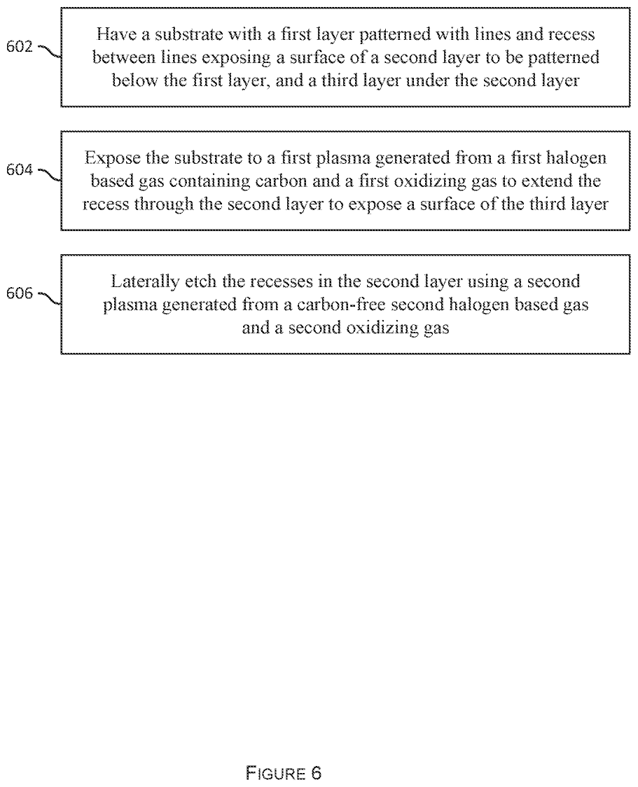

The invented plasma etch has been used in a method for patterning a layer of a multilayer stack of a substrate, as described above with reference to FIGS. 2-4B. This method is now summarized with reference to a flowchart in FIG. 6. The multilayer stack may be the multilayer stack 103 described above.

As indicated in box 602 of the flowchart in FIG. 6, a first layer of the multilayer stack may be the patterned top layer 210A in FIGS. 2-4B. The first layer comprises a plurality of lines, each of the plurality of lines being separated by a recess. A second layer of the multilayer stack below the second layer, which is the layer to be patterned, may be the middle layer 120 in FIG. 2. The bottom of the recess in the first layer exposes a surface of the second layer, same as the bottom of the recess 240 exposes a surface of the middle layer 120. A third layer of the multilayer stack under the second layer may be the bottom layer 110B in FIG. 2.

In box 604 of the flowchart in FIG. 6, the substrate is exposed to a first plasma that is same as the first plasma described above with reference to FIG. 3. The first plasma comprises a carbon containing first halogen based gas and a first oxidizing gas comprising oxygen. Exposing to the first plasma extends the recesses through the second layer to expose a surface of the third layer, same as the exposing the substrate to the first plasma extends the recess 240 to form the recess 340, the bottom of recess 340 exposing a surface of the bottom layer 110B, as described above with reference to FIG. 3.

In box 606 of the flowchart in FIG. 6, the recesses are etched laterally using a second plasma, same as the recesses 340 are etched laterally using the second plasma, as described above with reference to FIGS. 4A-4B.

Example embodiments of the invention are described below. Other embodiments can also be understood from the entirety of the specification as well as the claims filed herein.

Example 1. A method for patterning includes having a substrate including a first layer, a second layer to-be-patterned disposed under the first layer, and a third layer disposed under the second layer, the first layer including a plurality of lines, each of the plurality of lines being separated by a recess, a bottom of the recess exposing a surface of the second layer; exposing the substrate to a first plasma to extend the recesses through the second layer to expose a surface of the third layer, the first plasma being generated from a first halogen based gas and a first oxidizing gas, the first halogen based gas including a carbon-containing halogen based gas; and laterally etching the recesses in the second layer using a second plasma, the second plasma being generated from a second halogen based gas and a second oxidizing gas, the second halogen based gas being a carbon-free halogen based gas.

Example 2. The method of example 1, where the first halogen based gas includes a hydrofluorocarbon and the first oxidizing gas includes oxygen, and where the second halogen based gas includes NF3 and the second oxidizing gas includes oxygen.

Example 3. The method of one of examples 1 or 2, where the first oxidizing gas and the second oxidizing gas include molecular oxygen.

Example 4. The method of one of examples 1 to 3, where the first halogen based gas and the second halogen based gas include fluorine atoms.

Example 5. The method of one of examples 1 to 4, where the second layer includes a dielectric layer.

Example 6. The method of one of examples 1 to 5, where the dielectric layer includes silicon carbonitride.

Example 7. The method of one of examples 1 to 6, where the first layer includes a first nanosheet stack and the third layer includes a second nanosheet stack.

Example 8. A method for patterning includes having a stack over a surface of a base layer of a substrate, the stack including a patterned lithography stack over a multilayer stack, the multilayer stack including a middle layer, the middle layer disposed below a top layer and above a bottom layer, the top layer being patterned to have a plurality of lines; etching through the middle layer to expose the bottom layer using a first discharge gas, the etching extending the plurality of lines from the top layer into the middle layer, where a first line of the plurality of lines has a top critical dimension (T-CD) having a first T-CD value and a bottom critical dimension (B-CD) having a first B-CD value, the T-CD being the width of the first line at an intersection of the top layer and the middle layer, the B-CD being the width of the first line at an intersection of the middle layer and the bottom layer; and laterally etching the middle layer using a second discharge gas different from the first discharge gas, the lateral etching changing the T-CD of the first line from the first T-CD value to a second T-CD value and the B-CD of the first line from the first B-CD value to a second B-CD value, the difference between first T-CD value and the second T-CD value being less than the difference between first B-CD value and the second B-CD value.

Example 9. The method of example 8, where the difference between first T-CD value and the second T-CD value being less than 0.01 times the difference between first B-CD value and the second B-CD value.

Example 10. The method of one of examples 8 or 9, where the second discharge gas includes a flow of a halogen based gas and an oxidizing gas at a flow rate ratio, the flow rate ratio being a ratio of a flow rate of the halogen based gas to a flow rate of the oxidizing gas, where, prior to patterning, the flow rate ratio is selected such that the difference between first T-CD value and the second T-CD value is less than the difference between first B-CD value and the second B-CD value.

Example 11. The method of one of examples 8 to 10, further including: after laterally etching the middle layer, using the middle layer as an etch mask, anisotropically etching the bottom layer to expose a surface of the base layer of the substrate.

Example 12. The method of one of examples 8 to 11, where etching through the middle layer includes etching sidewall surfaces of the first line to be sloped in a direction that reduces a horizontal spacing between adjacent sidewall surfaces with increasing vertical distance from an intersection of the middle layer and the top layer.

Example 13. The method of one of examples 8 to 12, where laterally etching the middle layer includes etching the sidewall surfaces of the first line at a lateral etch rate that reduces with increasing vertical distance from an intersection of the middle layer and the bottom layer.

Example 14. The method of one of examples 8 to 13, where the second B-CD value is greater than or equal to the first T-CD value.

Example 15. The method of one of examples 8 to 14, where the second B-CD value is less than the first T-CD value.

Example 16. The method of one of examples 8 to 15, where the width of the first line changes monotonically from the second T-CD value to the second B-CD value in the middle layer.

Example 17. The method of one of examples 8 to 16, where the top layer includes a first nanosheet stack, the bottom layer includes a second nanosheet stack, and the middle layer includes a dielectric layer.

Example 18. The method of one of examples 8 to 17, where the dielectric layer includes silicon carbonitride.

Example 19. A method for patterning includes having a stack over a surface of a base layer of a substrate, the stack including a patterned lithography stack over a multilayer stack, the multilayer stack including a middle layer, the middle layer disposed below a top layer and above a bottom layer, the top layer being patterned to have a plurality of lines, a first line of the plurality of lines having a width; measuring the width of the first line to have a first width; determining an etching time for laterally etching the middle layer based on the first width; etching through the middle layer to expose the bottom layer using a first discharge gas, the etching extending the plurality of lines from the top layer into the middle layer; and laterally etching, for an overetch time, the middle layer using a second discharge gas different from the first discharge gas.

Example 20. The method of example 19, where determining the overetch time includes: applying a computational model calibrated with a plurality of test wafers processed with different overetch times for the laterally etching of the middle layer, the computation model being configured to select the overetch time based on a width of the plurality of lines in the top layer.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for patterning comprising:
having a substrate comprising a first layer, a second layer to-be-patterned disposed under the first layer, and a third layer disposed under the second layer, the first layer comprising a plurality of lines, each of the plurality of lines being separated by a recess, a bottom of the recess exposing a surface of the second layer;
exposing the substrate to a first plasma to extend the recesses through the second layer to expose a surface of the third layer, the first plasma being generated from a first halogen based gas and a first oxidizing gas, the first halogen based gas comprising a carbon-containing halogen based gas; and
laterally etching the recesses in the second layer using a second plasma, the second plasma being generated from a second halogen based gas and a second oxidizing gas, the second halogen based gas being a carbon-free halogen based gas.

2. The method of claim 1, wherein the first halogen based gas comprises a hydrofluorocarbon and the first oxidizing gas comprises oxygen, and wherein the second halogen based gas comprises NF₃ and the second oxidizing gas comprises oxygen.

3. The method of claim 2, wherein the first oxidizing gas and the second oxidizing gas comprise molecular oxygen.

4. The method of claim 1, wherein the first halogen based gas and the second halogen based gas comprise fluorine atoms.

5. The method of claim 1, wherein the second layer comprises a dielectric layer.

6. The method of claim 5, wherein the dielectric layer comprises silicon carbonitride.

7. The method of claim 1, wherein the first layer comprises a first nanosheet stack and the third layer comprises a second nanosheet stack.

8. A method for patterning comprising:
having a stack over a surface of a base layer of a substrate, the stack comprising a patterned lithography stack over a multilayer stack, the multilayer stack comprising a middle layer, the middle layer disposed below a top layer and above a bottom layer, the top layer being patterned to have a plurality of lines;
etching through the middle layer to expose the bottom layer using a first discharge gas, the etching extending the plurality of lines from the top layer into the middle layer, wherein a first line of the plurality of lines has a top critical dimension (T-CD) having a first T-CD value and a bottom critical dimension (B-CD) having a first B-CD value, the T-CD being the width of the first line at an intersection of the top layer and the middle layer, the B-CD being the width of the first line at an intersection of the middle layer and the bottom layer; and
laterally etching the middle layer using a second discharge gas different from the first discharge gas, the lateral etching changing the T-CD of the first line from the first T-CD value to a second T-CD value and the B-CD of the first line from the first B-CD value to a second B-CD value, the difference between first T-CD value and the second T-CD value being less than the difference between first B-CD value and the second B-CD value.

9. The method of claim 8, wherein the difference between first T-CD value and the second T-CD value being less than 0.01 times the difference between first B-CD value and the second B-CD value.

10. The method of claim 8, wherein the second discharge gas comprises a flow of a halogen based gas and an oxidizing gas at a flow rate ratio, the flow rate ratio being a ratio of a flow rate of the halogen based gas to a flow rate of the oxidizing gas, wherein, prior to patterning, the flow rate ratio is selected such that the difference between first T-CD value and the second T-CD value is less than the difference between first B-CD value and the second B-CD value.

11. The method of claim 8, further comprising:
after laterally etching the middle layer, using the middle layer as an etch mask, anisotropically etching the bottom layer to expose a surface of the base layer of the substrate.

12. The method of claim 8, wherein etching through the middle layer comprises etching sidewall surfaces of the first line to be sloped in a direction that reduces a horizontal spacing between adjacent sidewall surfaces with increasing vertical distance from an intersection of the middle layer and the top layer.

13. The method of claim 12, wherein laterally etching the middle layer comprises etching the sidewall surfaces of the first line at a lateral etch rate that reduces with increasing vertical distance from an intersection of the middle layer and the bottom layer.

14. The method of claim 8, wherein the second B-CD value is greater than or equal to the first T-CD value.

15. The method of claim 8, wherein the second B-CD value is less than the first T-CD value.

16. The method of claim 8, wherein the width of the first line changes monotonically from the second T-CD value to the second B-CD value in the middle layer.

17. The method of claim 8, wherein the top layer comprises a first nanosheet stack, the bottom layer comprises a second nanosheet stack, and the middle layer comprises a dielectric layer.

18. The method of claim 17, wherein the dielectric layer comprises silicon carbonitride.

19. A method for patterning comprising:
having a stack over a surface of a base layer of a substrate, the stack comprising a patterned lithography stack over a multilayer stack, the multilayer stack comprising a middle layer, the middle layer disposed below a top layer and above a bottom layer, the top layer being patterned to have a plurality of lines, a first line of the plurality of lines having a width;
measuring the width of the first line to have a first width;
determining an etching time for laterally etching the middle layer based on the first width;
etching through the middle layer to expose the bottom layer using a first discharge gas, the etching extending the plurality of lines from the top layer into the middle layer; and
laterally etching, for an overetch time, the middle layer using a second discharge gas different from the first discharge gas.

20. The method of claim 19, wherein determining the overetch time comprises:
applying a computational model calibrated with a plurality of test wafers processed with different overetch times for the laterally etching of the middle layer, the computation model being configured to select the overetch time based on a width of the plurality of lines in the top layer.
